(19) United States
(12) Patent Application Publication
(10) Pub. No.: US 2026/0031596 A1
(43) Pub. Date: Jan. 29, 2026

(54) VERTICAL-CAVITY SURFACE-EMITTING LASER DEVICE HAVING COMPOSITE OPTICAL FILM LAYER

(71) Applicant: HLJ TECHNOLOGY CO., LTD., Hsinchu County (TW)

(72) Inventors: YEN-CHUN TSENG, Hsinchu County (TW); BING-CHENG LIN, Hsinchu County (TW); LI-WEN LAI, Taoyuan City (TW); LI-HUNG LAI, Taoyuan City (TW)

(21) Appl. No.: 18/966,157

(22) Filed: Dec. 3, 2024

(30) Foreign Application Priority Data
Jul. 29, 2024 (TW) 113127996

(51) Int. Cl. H01S 5/183; H01S 5/042

(52) U.S. Cl. CPC H01S 5/18361; H01S 5/04253; H01S 5/18347

(57) ABSTRACT

A vertical-cavity surface-emitting laser device includes a substrate, at least one electrode layer, a first reflective layer, a plurality of active light-emitting layers, a plurality of second reflective layers, a plurality of first transparent conductive layers, and a composite optical film layer. The composite optical film layer is formed by stacking a plurality of optical film layers, and the composite optical film layer includes a plurality of bottom parts, a plurality of lateral parts, and a plurality of extension parts. A light outlet hole is defined between any two adjacent ones of the plurality of extension parts. A refractive index of each of the plurality of optical film layers in the composite optical film layer is gradually decreased from one of the plurality of optical film layers attached to a side wall surface to an outermost one of the plurality of optical film layers.

This application claims the benefit of priority to Taiwan Patent Application No. 113127996, filed on Jul. 29, 2024. The entire content of the above identified application is incorporated herein by reference.

### CROSS-REFERENCE TO RELATED PATENT APPLICATION

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a vertical-cavity surface-emitting laser device, and more particularly to a vertical-cavity surface-emitting laser device having a composite optical film layer.

### BACKGROUND OF THE DISCLOSURE

In the related art, an oxidation process is usually used in vertical-cavity surface-emitting laser devices to form a high-resistance oxide layer in the upper Bragg reflector to limit the area through which electric current flows. However, the cost of forming an oxide layer that limits current through an oxidation process is high and the pore size is large, which will affect the light-emitting effect. In addition, there are significant differences in the lattice mismatch and thermal expansion coefficient between the oxide layer that has undergone the oxidation process and the semiconductor material that constitutes the upper Bragg mirror, which can easily cause defects such as cracks due to internal stress, thus reducing the process yield, affecting the light-emitting performance, and reducing the reliability of components.

In addition, if the spatial distribution of the laser light of the vertical-cavity surface-emitting laser device is shown to be in a higher-order mode, due to its high power, the vertical-cavity surface-emitting laser device may not be applicable in communication technology fields that require low power.

Therefore, how to improve the light-emitting effect of the vertical-cavity surface-emitting laser device through structural design improvements to overcome the above-mentioned defects has become one of the important issues to be addressed in the industry.

### SUMMARY OF THE DISCLOSURE

In response to the above-referenced technical inadequacies, the present disclosure provides a vertical-cavity surface-emitting laser device having a composite optical film layer.

In order to solve the above-mentioned problems, one of the technical aspects adopted by the present disclosure is to provide a vertical-cavity surface-emitting laser device. The vertical-cavity surface-emitting laser device includes a substrate, at least one electrode layer, a first reflective layer, a plurality of active light-emitting layers, a plurality of second reflective layers, a plurality of first transparent conductive layers, and a composite optical film layer. The substrate has a top surface and a bottom surface. The at least one electrode layer is disposed on the bottom surface. The first reflective layer is disposed on the top surface. The first reflective layer includes a base part and a plurality of reflective parts, the plurality of reflective parts are arranged at intervals on the base part, and two adjacent ones of the reflective parts are spaced apart by a distance. A plurality of exposed surfaces are defined by areas on the surface of the first reflective layer that do not have the plurality of reflective parts. The plurality of active light-emitting layers are respectively located on the plurality of reflective parts. The plurality of second reflective layers are respectively located on the plurality of active light-emitting layers. The plurality of first transparent conductive layers are respectively located on the plurality of second reflective layers. The composite optical film layer is formed by stacking a plurality of optical film layers. The composite optical film layer includes a plurality of bottom parts, a plurality of lateral parts, and a plurality of extension parts. Two sides of each of the plurality of bottom parts are respectively connected to one ends of two corresponding ones of the plurality of lateral parts, and each of the plurality of extension parts is connected to another end of the corresponding one of the plurality of lateral parts. A side wall surface is defined by a same side of each of the reflective parts, each of the plurality of active light-emitting layers, and each of the plurality of second reflective layers, the lateral parts cover the side wall surface, and the bottom parts cover the exposed surfaces. Each of the plurality of extension parts is located between the plurality of first transparent conductive layers and the plurality of second reflective layers, and corresponds to the plurality of transparent conductive layers, and a light outlet hole is defined between any two adjacent ones of the plurality of extension parts. A refractive index of each of the plurality of optical film layers in the composite optical film layer is gradually decreased from one of the plurality of optical film layers attached to the side wall surface to an outermost one of the plurality of optical film layers.

In one of the possible or preferred embodiments, the vertical-cavity surface-emitting laser device further includes a plurality of filling bodies. Each of the plurality of filling bodies is a conductive material or a dielectric material. A tank body is formed by the bottom part and the two corresponding lateral parts connected to the bottom part, and each of the plurality of filling bodies includes a filling part and a connecting part that are connected to each other. The filling part is filled in the tank body, and two ends of the connecting part are connected to two adjacent ones of the first transparent conductive layers, respectively.

In order to solve the above-mentioned problems, another one of the technical aspects adopted by the present disclosure is to provide a vertical-cavity surface-emitting laser device. The vertical-cavity surface-emitting laser device includes a substrate, at least one electrode layer, a first reflective layer, a plurality of active light-emitting layers, a plurality of second reflective layers, a plurality of first transparent conductive layers, and a composite optical film layer. The substrate has a top surface and a bottom surface. The at least one electrode layer is disposed on the bottom surface. The first reflective layer is disposed on the top surface. The first reflective layer includes a base part and a plurality of reflective parts, the plurality of reflective parts are arranged at intervals on the base part, and two adjacent ones of the reflective parts are spaced apart by a distance. A plurality of exposed surfaces are defined by areas on the surface of the first reflective layer that do not have the plurality of reflective parts. The plurality of active light-emitting layers are respectively located on the plurality of reflective parts. The plurality of second reflective layers are respectively located on the plurality of active light-emitting layers. The plurality of first transparent conductive layers are respectively located on the plurality of second reflective layers. The composite optical film layer is formed by stacking a plurality of optical film layers. The composite optical film layer includes a plurality of bottom parts, a plurality of lateral parts, and a plurality of extension parts. Two sides of each of the plurality of bottom parts are respectively connected to one ends of two corresponding ones of the plurality of lateral parts, and each of the plurality of extension parts is connected to another end of the corresponding one of the plurality of lateral parts. A side wall surface is defined by a same side of each of the reflective parts, each of the plurality of active light-emitting layers, and each of the plurality of second reflective layers, the lateral parts cover the side wall surface, and the bottom parts cover the exposed surfaces. Each of the plurality of extension parts is located on the plurality of first transparent conductive layers and corresponds to the plurality of transparent conductive layers, and a light outlet hole is defined between any two adjacent ones of the plurality of extension parts. A refractive index of each of the plurality of optical film layers in the composite optical film layer is gradually decreased from one of the plurality of optical film layers attached to the side wall surface to an outermost one of the plurality of optical film layers.

In one of the possible or preferred embodiments, the vertical-cavity surface-emitting laser device further includes a plurality of filling bodies. Each of the plurality of filling bodies is a conductive material or a dielectric material. A tank body is formed by the bottom part and the two corresponding lateral parts connected to the bottom part. The filling part is filled in the tank body.

In one of the possible or preferred embodiments, the composite optical film layer further includes a second transparent conductive layer attached to the side wall surface.

In one of the possible or preferred embodiments, the composite optical film layer further includes a second transparent conductive layer that is the outermost one of the plurality of optical film layers.

In one of the possible or preferred embodiments, the composite optical film layer further includes a second transparent conductive layer located between one of the plurality of optical film layer that is attached to the side wall surface and the outermost one of the plurality of optical film layers of the composite optical film layer.

In one of the possible or preferred embodiments, the at least one electrode layer is plural in quantity, and the plurality of electrode layers correspond to each of the reflective parts in position. A length of each of the plurality of electrode layers in a first direction is less than or equal to a length of each of the plurality of first transparent conductive layers in the first direction.

In one of the possible or preferred embodiments, the first transparent conductive layer is a metal film or an indium tin oxide layer.

Therefore, one of the advantageous effects of the present disclosure is that, in the vertical-cavity surface-emitting laser device having a composite optical film layer provided by the present disclosure, by the configuration of the composite optical film layer, the spatial distribution of laser light when the vertical-cavity surface-emitting laser device enters the higher-order mode can be effectively suppressed, such that the vertical-cavity surface-emitting laser device meets requirements of the spatial distribution of laser light of a single-mode vertical-cavity surface-emitting laser device.

Furthermore, another one of the advantageous effects of the present disclosure is that, the vertical-cavity surface-emitting laser device having a composite optical film layer provided by the present disclosure does not include a current-limiting layer that is an oxidation layer formed by using an oxidation process. Accordingly, defects generated from the oxidation process are absent from the vertical-cavity surface-emitting laser device, thereby improving the quality of the vertical-cavity surface-emitting laser device.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a vertical-cavity surface-emitting laser device having a composite optical film layer according to one embodiment of the present disclosure;

FIG. 2 is another schematic cross-sectional view of the vertical-cavity surface-emitting laser device having the composite optical film layer according to one embodiment of the present disclosure;

FIG. 3 is a schematic partial cross-sectional view of the vertical-cavity surface-emitting laser device having the composite optical film layer according to one embodiment of the present disclosure;

FIG. 4 is another schematic partial cross-sectional view of the vertical-cavity surface-emitting laser device having the composite optical film layer according to one embodiment of the present disclosure;

FIG. 5 is yet another schematic partial cross-sectional view of the vertical-cavity surface-emitting laser device having the composite optical film layer according to one embodiment of the present disclosure;

FIG. 6 is still another schematic partial cross-sectional view of the vertical-cavity surface-emitting laser device having the composite optical film layer according to one embodiment of the present disclosure;

FIG. 7 is still another schematic partial cross-sectional view of the vertical-cavity surface-emitting laser device having the composite optical film layer according to one embodiment of the present disclosure;

FIG. 8 is still another schematic partial cross-sectional view of the vertical-cavity surface-emitting laser device having the composite optical film layer according to one embodiment of the present disclosure;

FIG. 9 is still another schematic partial cross-sectional view of the vertical-cavity surface-emitting laser device having the composite optical film layer according to one embodiment of the present disclosure;

FIG. 10 is still another schematic cross-sectional view of the vertical-cavity surface-emitting laser device having the composite optical film layer according to one embodiment of the present disclosure; and

FIG. 11 is still another schematic cross-sectional view of the vertical-cavity surface-emitting laser device having the composite optical film layer according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Embodiments

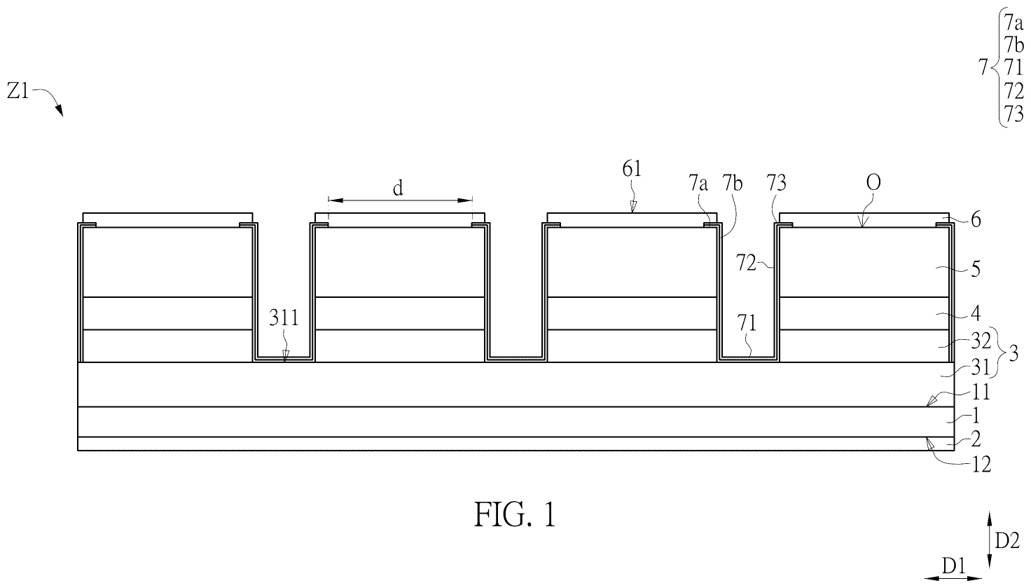

Referring to FIG. 1, FIG. 1 is a schematic cross-sectional view of a vertical-cavity surface-emitting laser device Z1 having a composite optical film layer according to one embodiment of the present disclosure. The vertical-cavity surface-emitting laser device Z1 having a composite optical film layer 7 includes: a substrate 1, an electrode layer 2, a first reflective layer 3, a plurality of active light-emitting layers 4, a plurality of second reflective layers 5, a plurality of first transparent conductive layers 6, and a composite optical film layer 7. The substrate 1 has a top surface 11 and a bottom surface 12. The electrode layer 2 is disposed on the bottom surface 12. The first reflective layer 3 is disposed on the top surface 11. The first reflective layer 3 includes a base part 31 and a plurality of reflective parts 32. The plurality of reflective parts 32 are arranged at intervals on the base part 31, and two adjacent ones of the reflective parts 32 are spaced apart by a distance. A plurality of exposed surfaces 311 are defined by areas on the surface of the first reflective layer 3 that do not have the plurality of reflective parts 32. The plurality of active light-emitting layers 4 are respectively located on the plurality of reflective parts 32. The plurality of second reflective layers 5 are respectively located on the plurality of active light-emitting layers 4. The plurality of first transparent conductive layers 6 are respectively located on the plurality of second reflective layers 5. The composite optical film layer 7 is formed by stacking a plurality of optical film layers (the following descriptions take two or three optical film layers as an example, but the present disclosure is not limited thereto). The composite optical film layer 7 includes a plurality of bottoms parts 71, a plurality of lateral parts 72, and a plurality of extension parts 73. Two sides of each of the plurality of bottom parts 71 are respectively connected to one ends of two corresponding ones of the plurality of lateral parts 72, and each of the plurality of extension parts 73 is connected to another end of the corresponding one of the plurality of lateral parts 72. A side wall surface S is defined by a same side of each of the reflective part 32, each of the plurality of active light-emitting layers 4, and each of the second reflective layers 5, the lateral parts 72 cover the side wall surface S, and the bottom parts 71 cover the exposed surfaces 311. Each of the plurality of extension parts 73 is located between the plurality of first transparent conductive layers 6 and the plurality of second reflective layers 5, and corresponds to the plurality of first transparent conductive layers 6, and a light outlet hole O is defined between any two adjacent ones of the plurality of extension parts 73. In the composite optical film layer 7, a refractive index of each of the plurality of optical film layers in the composite optical film layer 7 is gradually decreased from one of the plurality of optical film layers attached to the side wall surface S to an outermost one of the plurality of optical film layers.

The substrate 1 may be an insulating substrate or a semiconductor substrate. The insulating substrate is, for example, sapphire, and the semiconductor substrate is, for example, silicon, germanium, silicon carbide, or Group III-V semiconductors. Group III-V semiconductors are, for example, gallium arsenide (GaAs), indium phosphide (InP), aluminum nitride (AlN), indium nitride (InN), or gallium nitride (GaN). According to certain embodiments, the electrode layer 2 is made of metal or alloy and is disposed on the bottom surface 12 of the substrate 1. According to certain embodiments, the first reflective layer 3 and the second reflective layers 5 are distributed Bragg reflectors (DBR) formed by alternately stacking two types of films having different refractive indexes, such that the first reflective layer 3 and the second reflective layers 5 have a light beam reflection resonance of a predetermined wavelength. According to certain embodiments, the materials of the first reflective layer 3 and the second reflective layers 5 may be semiconductors doped with Group III-V compounds. According to certain embodiments, the first reflective layer 3 and the second reflective layers 5 respectively have different conductivity types. For example, the first reflective layer 3 is an N-type semiconductor layer, and the second reflective layers 5 are P-type semiconductor layers. According to certain embodiments, each of the first transparent conductive layers 6 is an indium tin oxide layer having light-transmitting and conductive properties and can be used for electrical connection. In certain embodiments, an additional electrode layer 2 (or an electrical contact) can be disposed or can be not disposed on a surface 61 of the first transparent conductive layer 6. According to certain embodiments, the first transparent conductive layers 6 can also be metal films. When the metal film reaches a certain thickness, the metal film can also be light-transmissive and can also be used in vertical-cavity surface-emitting laser devices.

According to certain embodiments, the base part 31 and the plurality of reflective parts 32 are formed by etching the first reflective layer 3, and the plurality of reflective parts 32 are arranged in an array on the base part 31. For example, after disposing the first reflective layer 3 (i.e., configuring a thickness), the active light-emitting layer 4, and the second reflective layer 5, the second reflective layer 5, the active light-emitting layer 4, and the first reflective layer 3 are sequentially etched in a second direction D2 (e.g., a vertical direction); that is, the base part 31 and the plurality of reflective parts 32 can be formed in the first reflective layer 3. However, the present disclosure is not limited thereto. In certain embodiments, the base part 31 can also be provided first, then a reflective layer can be disposed on the base part 31, and the plurality of reflective parts 32 can be formed through etching.

According to certain embodiments, a diameter of the light outlet hole O is less than or equal to 10 μm. That is, in certain embodiments, the length of a mesa in a first direction D1 is slightly greater than 10 μm. The aforementioned mesa includes a reflective part 32, an active light-emitting layer 4, a second reflective layer 5, and a first transparent conductive layer 6. In certain embodiments, according to this structure, since the diameter d of the light outlet hole O is small, a light beam can be emitted in a substantially straight direction, which has a light-concentration effect.

According to the embodiment shown in FIG. 1, the composite optical film layer 7 includes two optical film layers that are respectively defined as a first optical film layer 7a and a second optical film layer 7b. The refractive index of the first optical film layer 7a is greater than the refractive index of the second optical film layer 7b. The composite optical film layer 7 is a graded refractive index composite film layer, such as an anti-reflective coating film (an AR Film). According to certain embodiments, each of the optical film layers can be made of the following materials: SiO/Ge/Al or magnesium fluoride (MgF₂). However, the present disclosure is not limited thereto. The refractive index of each of the optical film layers gradually decreases from the optical film layer attached to the side wall surface S to the outermost optical film layer, and such configuration can effectively suppress the spatial distribution of laser light when the vertical-cavity surface-emitting laser device enters the higher-order mode. The vertical-cavity surface-emitting laser device of the present disclosure can be used in the communication field, the vertical-cavity surface-emitting laser device meets requirements of the spatial distribution of laser light of a single-mode vertical-cavity surface-emitting laser device, and the power of the laser is relatively low.

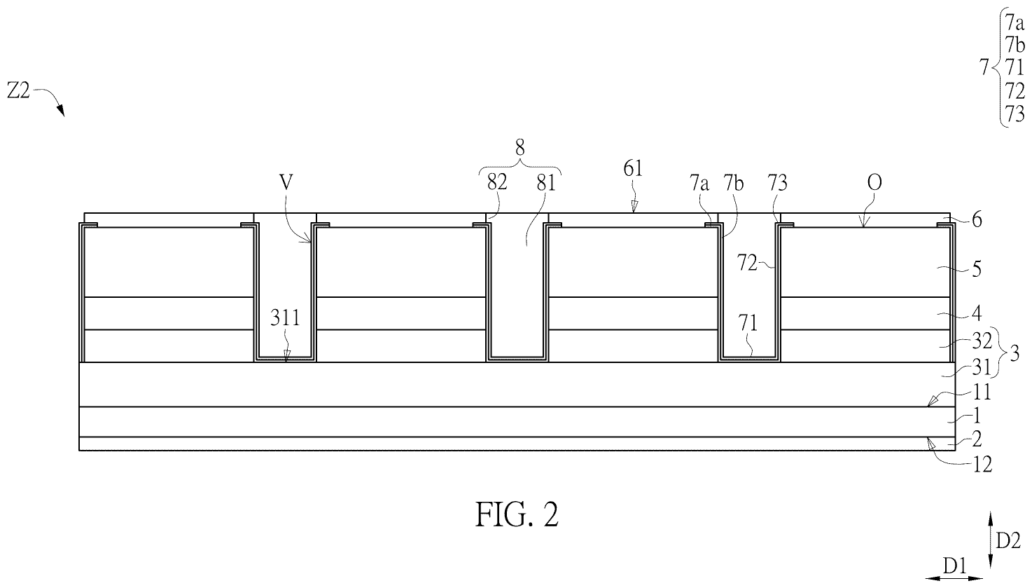

Referring to FIG. 2, FIG. 2 is a cross-sectional view of a vertical-cavity surface-emitting laser device Z2 having a composite optical film layer according to one embodiment of the present disclosure. In this embodiment, the vertical-cavity surface-emitting laser device Z2 having the composite optical film layer 7 further includes a plurality of filling bodies 8, and each of the filling bodies 8 is a conductive material or a dielectric material. A tank body V is formed by the bottom part 71 and the two corresponding lateral parts 72 connected to the bottom part 71. Each of the filling bodies 8 includes a filling part 81 and a connecting part 82 that are connected to each other. The filling part 81 is filled in the tank body V, and two ends of the connecting part 82 are connected to two adjacent ones of the first transparent conductive layers 6, respectively.

According to certain embodiments, the filling body 8 is a metal or an alloy, such as copper metal having the effect of guiding an electric current to flow to the electrode layer 2. In addition, the filling body 8 being made of the metal or the alloy can further improve the heat dissipation performance of the vertical-cavity surface-emitting laser device having the composite optical film layer 7.

According to certain embodiments, the filling body 8 is a dielectric material, such as polyimide (PI).

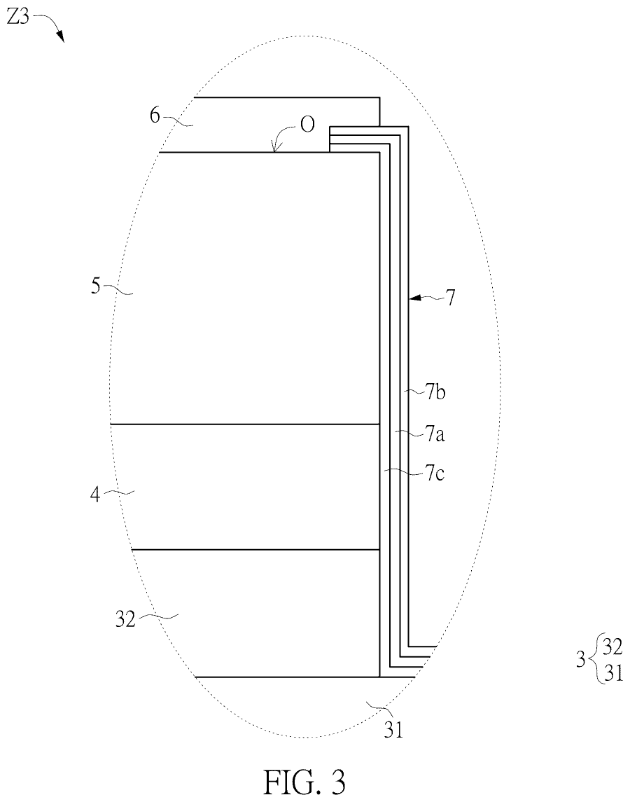

Reference is made to FIGS. 3 to 5, which are partial cross-sectional views of vertical-cavity surface-emitting laser devices Z3 to Z5 having composite optical film layers according to embodiments of the present disclosure. According to these embodiments, the composite optical film layer 7 further includes a second transparent conductive layer 7c.

The position of the second transparent conductive layer 7c can be located at an innermost side of the composite optical film layer; for example, the second transparent conductive layer 7c can be attached to the side wall surface S, as shown in FIG. 3. In the embodiment shown in FIG. 3, the refractive index of the second transparent conductive layer 7c is greater than the refractive index of the first optical film layer 7a, and the refractive index of the first optical film layer 7a is greater than the refractive index of the second optical film layer 7b.

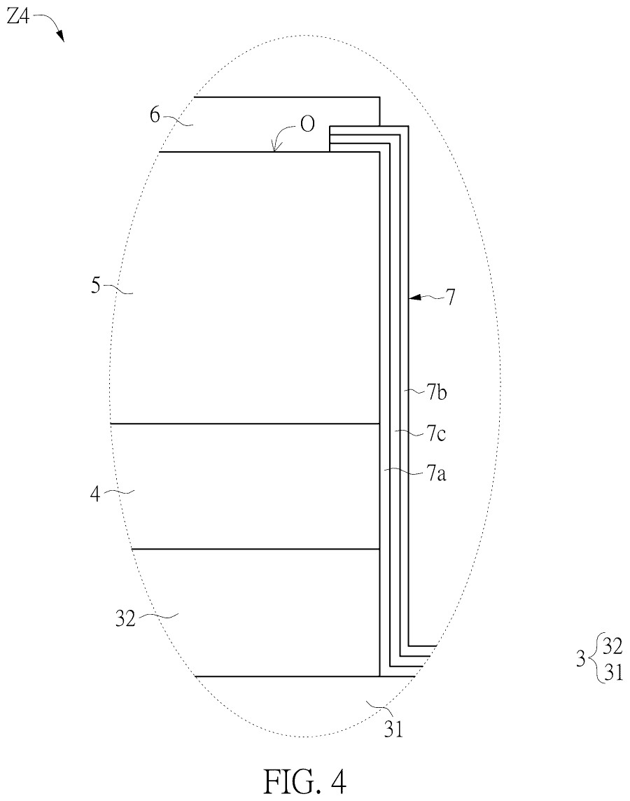

The second transparent conductive layer 7c can also be located between the optical film layer attached to the side wall surface S and the outermost optical film layer in the composite optical film layer 7, as shown in FIG. 4. In the embodiment shown in FIG. 4, the refractive index of the first optical film layer 7a is greater than the refractive index of the second transparent conductive layer 7c, and the refractive index of the second transparent conductive layer 7c is greater than the refractive index of the second optical film layer 7b.

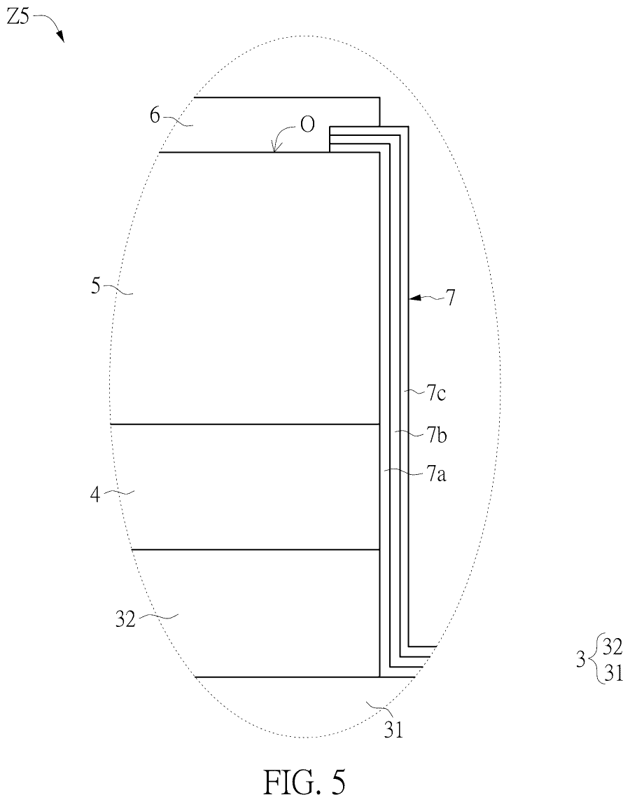

In addition, the second transparent conductive layer 7c can be used as the outermost optical film layer in the composite optical film layer 7. In other words, the second transparent conductive layer 7c can also be located at the outermost side of the composite optical film layer 7, as shown in FIG. 5. According to the embodiment shown in FIG. 5, the refractive index of the first optical film layer 7a is greater than the refractive index of the second optical film layer 7b, and the refractive index of the second optical film layer 7b is greater than the refractive index of the second transparent conductive layer 7c.

In certain embodiments, the second transparent conductive layer 7c is made of the same material as the first transparent conductive layer 6, and is connected to the first transparent conductive layer 6. For example, the first transparent conductive layer 6 and the second transparent conductive layer 7c are both made of indium tin oxide.

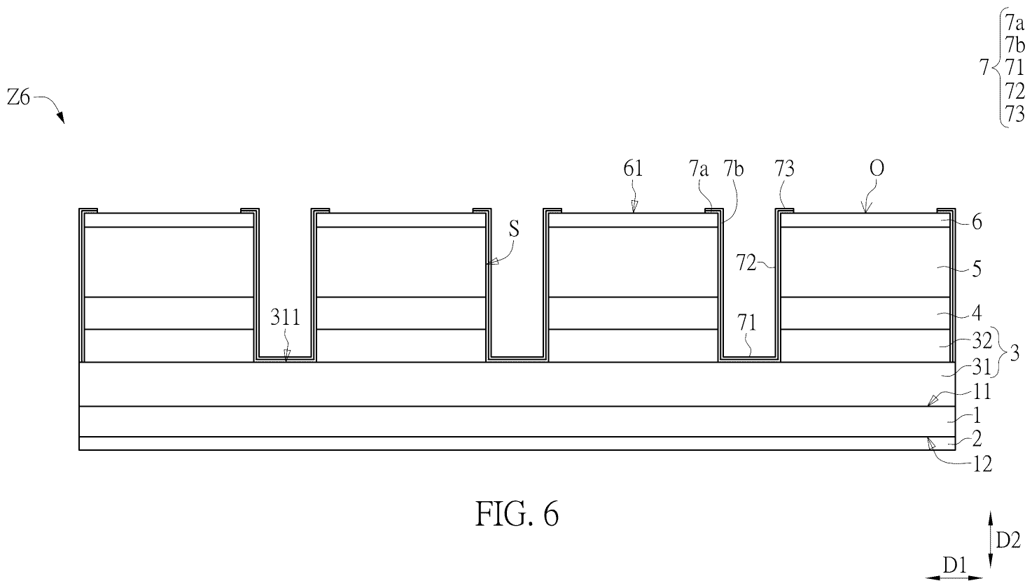

Reference is made to FIG. 6, which is a cross-sectional view of a vertical-cavity surface-emitting laser device Z6 having a composite optical film layer according to one embodiment of the present disclosure. A difference between this embodiment and the embodiment shown in FIG. 1 is that, in the embodiment shown in FIG. 6, the extension parts 73 of the composite optical film layer 7 are located on the first transparent conductive layer 6. Such configuration can effectively suppress the spatial distribution of laser light when the vertical-cavity surface-emitting laser device enters the higher-order mode. The vertical-cavity surface-emitting device laser of the present disclosure can be used in the communication field, the vertical-cavity surface-emitting laser device meets requirements of the spatial distribution of laser light of a single-mode vertical-cavity surface-emitting laser device, and the power of the laser is relatively low.

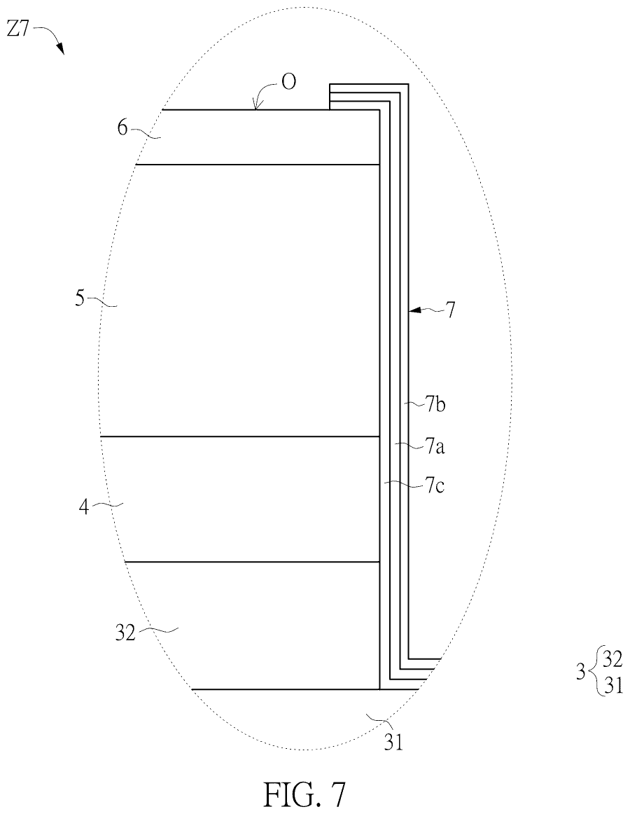

Reference is made to FIGS. 7 to 9, which are partial cross-sectional views of vertical-cavity surface-emitting laser devices Z7 to Z9 having composite optical film layers according to embodiments of the present disclosure. According to these embodiments, the composite optical film layer 7 further includes a second transparent conductive layer 7c.

According to the embodiment shown in FIG. 7, the second transparent conductive layer 7c is attached to the side wall surface S. The refractive index of the second transparent conductive layer 7c is greater than the refractive index of the first optical film layer 7a, and the refractive index of the first optical film layer 7a is greater than the refractive index of the second optical film layer 7b.

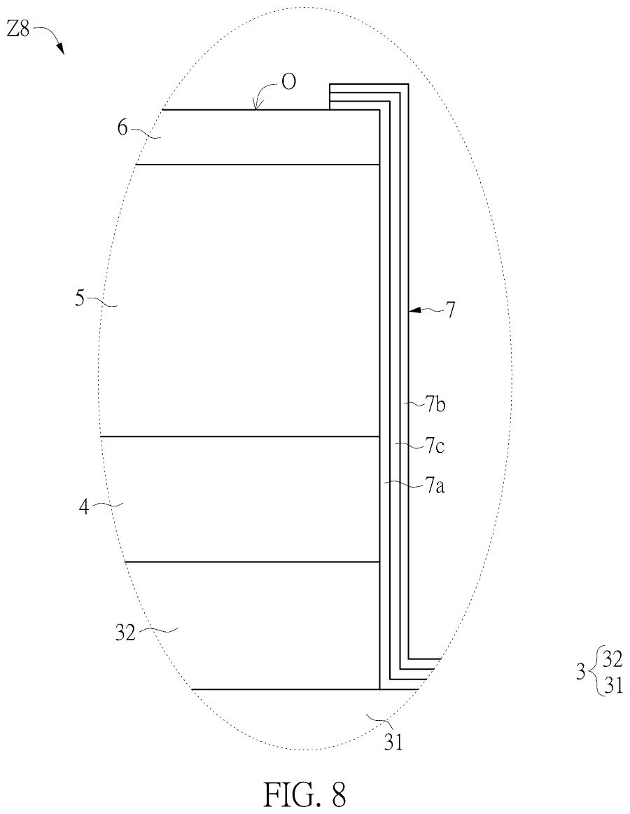

According to the embodiment shown in FIG. 8, the second transparent conductive layer 7c is located between the optical film layer attached to the side wall surface S and the outermost optical film layer of the composite optical film layer 7. As shown in FIG. 8, the second transparent conductive layer 7c is located between the first optical film layer 7a and the second optical film layer 7b. At this time, the refractive index of the first optical film layer 7a is greater than the refractive index of the second transparent conductive layer 7c, and the refractive index of the second transparent conductive layer 7c is greater than the refractive index of the second optical film layer 7b.

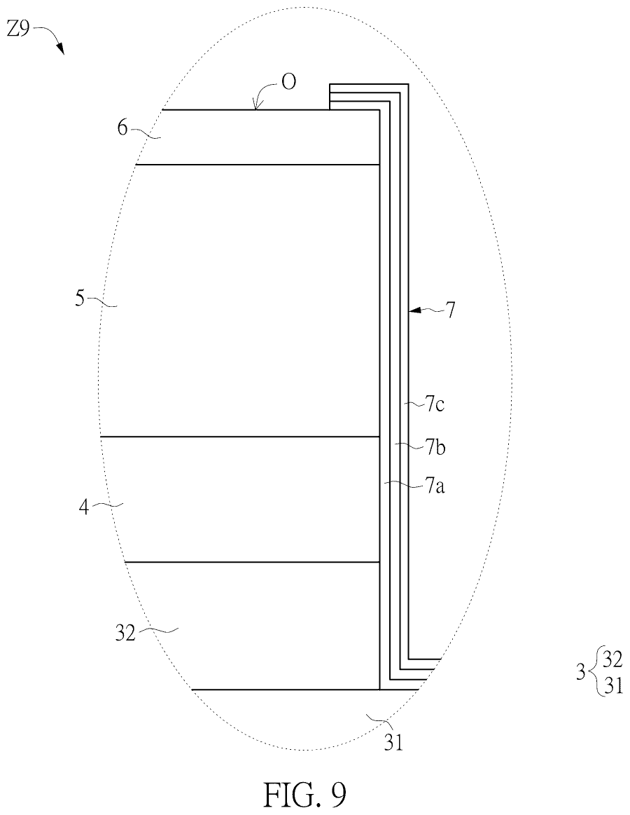

According to the embodiment shown in FIG. 9, the second transparent conductive layer 7c is located at the outermost side of the composite optical film layer 7. The refractive index of the first optical film layer 7a is greater than the refractive index of the second optical film layer 7b, and the refractive index of the second optical film layer 7b is greater than the refractive index of the second transparent conductive layer 7c.

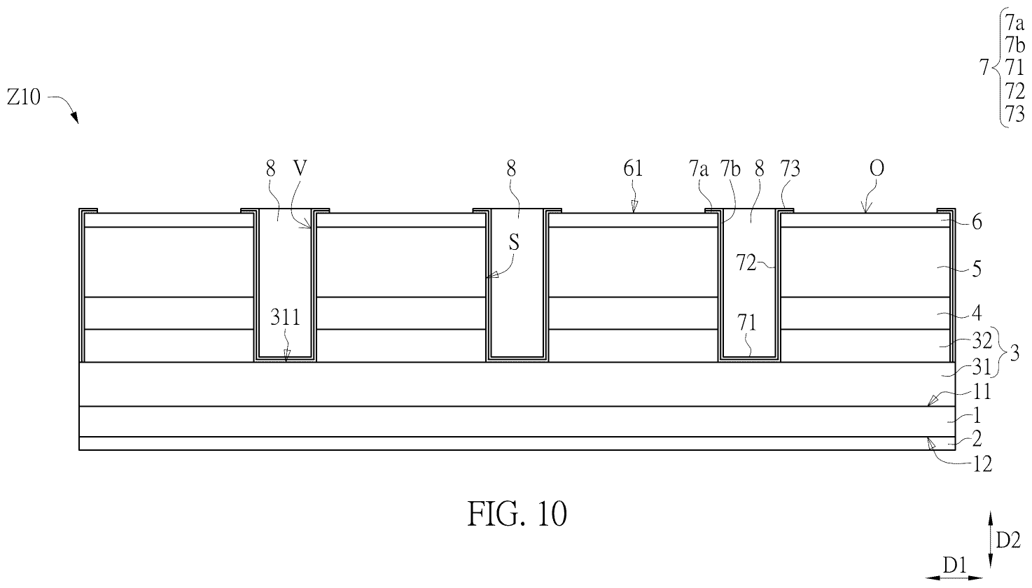

Reference is made to FIG. 10, which is a cross-sectional view of a vertical-cavity surface-emitting laser device Z10 having a composite optical film layer according to one embodiment of the present disclosure. The vertical-cavity surface-emitting laser device Z10 having the composite optical film layer 7 further includes a plurality of filling bodies 8, and each of the filling bodies 8 is a conductive material or a dielectric material. The filling bodies 8 are filled in the tank body V. When each of the filling bodies 8 is made of a metal or an alloy, the heat dissipation performance of the vertical-cavity surface-emitting laser device and the reliability of the product can be improved. The filling body 8 can be a dielectric material, such as polyimide (PI).

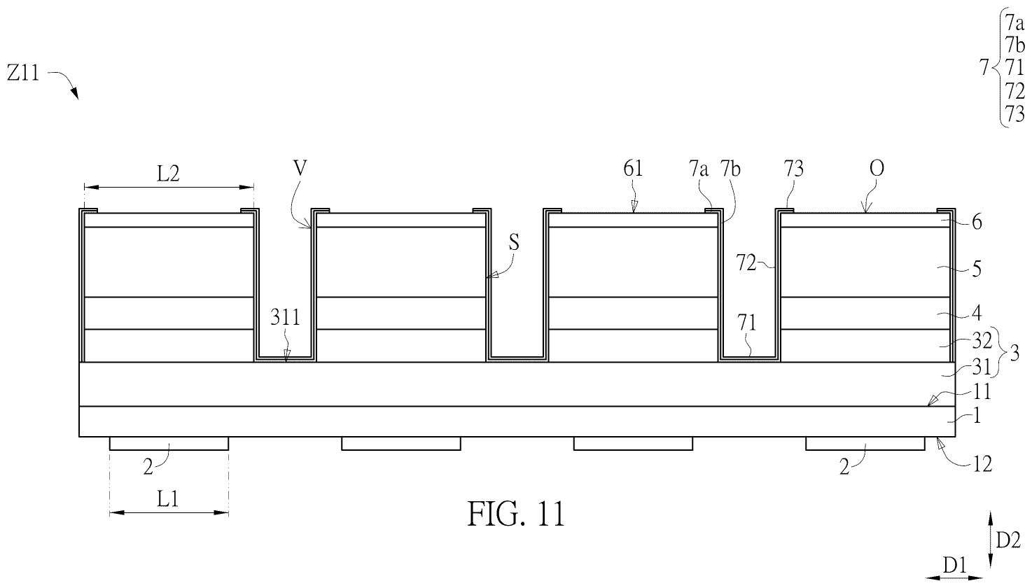

Reference is made to FIG. 11, which is a cross-sectional view of a vertical-cavity surface-emitting laser device Z11 having a composite optical film layer according to one embodiment of the present disclosure. In this embodiment, the electrode layer 2 is plural in quantity, and the electrode layers 2 correspond to each of the reflective parts 32 in position, respectively. A length L1 of each of the electrode layers 2 in the first direction D1 is less than or equal to a length L2 of each of the first transparent conductive layers 6 in the first direction D1. The side wall surface S formed on the same side of the reflective parts 32, the active light-emitting layer 4, the second reflective layer 5, and the transparent conductive layer 6 may have defects, and is not conducive to the flow of electric current. Therefore, by the design of the length L1 of the electrode layers 2 being less than or equal to the length L2 of the first transparent conductive layers 6 (in other words, less than or equal to the length of the mesa), electric current can easily flow to the electrode layers 2 in a concentrated manner.

### Beneficial Effects of the Embodiments

In conclusion, one of the advantageous effects of the present disclosure is that, in the vertical-cavity surface-emitting laser device having a composite optical film layer provided by the present disclosure, by virtue of disposing the composite optical film layer, the spatial distribution of laser light when the vertical-cavity surface-emitting laser device enters the higher-order mode can be effectively suppressed, such that the vertical-cavity surface-emitting laser device meets requirements of the spatial distribution of laser light of a single-mode vertical-cavity surface-emitting laser device.

Furthermore, another one of the advantageous effects of the present disclosure is that, the vertical-cavity surface-emitting laser device having a composite optical film layer provided by the present disclosure does not include a current-limiting layer that is an oxidation layer formed by using an oxidation process. Accordingly, defects generated from the oxidation process are absent from the vertical-cavity surface-emitting laser device, thereby improving the quality of the vertical-cavity surface-emitting laser device.

Moreover, according to one embodiment of the present disclosure, the size of the mesa of the vertical-cavity surface-emitting laser device is simplified, and the diameter of the light outlet hole is small, such that the light beam is emitted from the light outlet hole in a nearly straight manner, and the light is concentrated to improve the light-emitting effect of the vertical-cavity surface-emitting laser device.

In addition, according to one embodiment of the present disclosure, a metal filling body is filled in the tank body of the vertical-cavity surface-emitting laser device, so as to increase the heat dissipation function of the vertical-cavity surface-emitting laser device. Further, the connection between the filling body and the first transparent conductive layer can also allow the electric current flow to be consistent, thereby improving the efficiency of the vertical-cavity surface-emitting laser device. Further, according to one embodiment of the present disclosure, a dielectric material is filled in the tank body of the vertical-cavity surface-emitting laser device.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A vertical-cavity surface-emitting laser device, comprising:
a substrate having a top surface and a bottom surface;
at least one electrode layer disposed on the bottom surface;
a first reflective layer disposed on the top surface, wherein the first reflective layer includes a base part and a plurality of reflective parts, the plurality of reflective parts are arranged at intervals on the base part, and two adjacent ones of the reflective parts are spaced apart by a distance;
wherein a plurality of exposed surfaces are defined by areas on the surface of the first reflective layer that do not have the plurality of reflective parts;
a plurality of active light-emitting layers respectively located on the plurality of reflective parts;
a plurality of second reflective layers respectively located on the plurality of active light-emitting layers;
a plurality of first transparent conductive layers respectively located on the plurality of second reflective layers; and
a composite optical film layer formed by stacking a plurality of optical film layers, wherein the composite optical film layer includes a plurality of bottom parts, a plurality of lateral parts, and a plurality of extension parts; wherein two sides of each of the plurality of bottom parts are respectively connected to one ends of two corresponding ones of the plurality of lateral parts, and each of the plurality of extension parts is connected to another end of the corresponding one of the plurality of lateral parts; wherein a side wall surface is defined by a same side of each of the reflective parts, each of the plurality of active light-emitting layers, and each of the plurality of second reflective layers, the lateral parts cover the side wall surface, and the bottom parts cover the exposed surfaces; wherein each of the plurality of extension parts is located between the plurality of first transparent conductive layers and the plurality of second reflective layers, and corresponds to the plurality of transparent conductive layers, and a light outlet hole is defined between any two adjacent ones of the plurality of extension parts;
wherein a refractive index of each of the plurality of optical film layers in the composite optical film layer is gradually decreased from one of the plurality of optical film layers attached to the side wall surface to an outermost one of the plurality of optical film layers.

2. The vertical-cavity surface-emitting laser device according to claim 1, further comprising a plurality of filling bodies, wherein each of the plurality of filling bodies is a conductive material or a dielectric material; wherein a tank body is formed by the bottom part and the two corresponding lateral parts connected to the bottom part, and each of the plurality of filling bodies includes a filling part and a connecting part that are connected to each other; wherein the filling part is filled in the tank body, and two ends of the connecting part are connected to two adjacent ones of the first transparent conductive layers, respectively.

3. The vertical-cavity surface-emitting laser device according to claim 1, wherein the composite optical film layer further includes a second transparent conductive layer attached to the side wall surface.

4. The vertical-cavity surface-emitting laser device according to claim 1, wherein the composite optical film layer further includes a second transparent conductive layer that is the outermost one of the plurality of optical film layers.

5. The vertical-cavity surface-emitting laser device according to claim 1, wherein the composite optical film layer further includes a second transparent conductive layer located between one of the plurality of optical film layer that is attached to the side wall surface and the outermost one of the plurality of optical film layers of the composite optical film layer.

6. The vertical-cavity surface-emitting laser device according to claim 1, wherein the at least one electrode layer is plural in quantity, and the plurality of electrode layers correspond to each of the reflective parts in position; wherein a length of each of the plurality of electrode layers in a first direction is less than or equal to a length of each of the plurality of first transparent conductive layers in the first direction.

7. The vertical-cavity surface-emitting laser device according to claim 1, wherein the first transparent conductive layer is a metal film or an indium tin oxide layer.

8. A vertical-cavity surface-emitting laser device, comprising:
a substrate having a top surface and a bottom surface;
at least one electrode layer disposed on the bottom surface;
a first reflective layer disposed on the top surface, wherein the first reflective layer includes a base part and a plurality of reflective parts, the plurality of reflective parts are arranged at intervals on the base part, and two adjacent ones of the reflective parts are spaced apart by a distance;
wherein a plurality of exposed surfaces are defined by areas on the surface of the first reflective layer that do not have the plurality of reflective parts;
a plurality of active light-emitting layers respectively located on the plurality of reflective parts;
a plurality of second reflective layers respectively located on the plurality of active light-emitting layers;
a plurality of first transparent conductive layers respectively located on the plurality of second reflective layers; and
a composite optical film layer formed by stacking a plurality of optical film layers, wherein the composite optical film layer includes a plurality of bottom parts, a plurality of lateral parts, and a plurality of extension parts; wherein two sides of each of the plurality of bottom parts are respectively connected to one ends of two corresponding ones of the plurality of lateral parts, and each of the plurality of extension parts is connected to another end of the corresponding one of the plurality of lateral parts; wherein a side wall surface is defined by a same side of each of the reflective parts, each of the plurality of active light-emitting layers, and each of the plurality of second reflective layers, the lateral parts cover the side wall surface, and the bottom parts cover the exposed surfaces; wherein each of the plurality of extension parts is located on the plurality of first transparent conductive layers and corresponds to the plurality of transparent conductive layers, and a light outlet hole is defined between any two adjacent ones of the plurality of extension parts;
wherein the refractive index of each of the plurality of optical film layers in the composite optical film layer is gradually decreased from one of the plurality of optical film layers attached to the side wall surface to an outermost one of the plurality of optical film layers.

9. The vertical-cavity surface-emitting laser device according to claim 8, wherein the composite optical film layer further includes a second transparent conductive layer attached to the side wall surface.

10. The vertical-cavity surface-emitting laser device according to claim 8, wherein the composite optical film layer further includes a second transparent conductive layer located between one of the plurality of optical film layer that is attached to the side wall surface and the outermost one of the plurality of optical film layers of the composite optical film layer.

11. The vertical-cavity surface-emitting laser device according to claim 8, wherein the composite optical film layer further includes a second transparent conductive layer that is the outermost one of the plurality of optical film layers.

12. The vertical-cavity surface-emitting laser device according to claim 8, further comprising a plurality of filling bodies, wherein each of the plurality of filling bodies is a conductive material or a dielectric material; wherein a tank body is formed by the bottom part and the two corresponding lateral parts connected to the bottom part; wherein the filling part is filled in the tank body.

13. The vertical-cavity surface-emitting laser device according to claim 8, wherein the at least one electrode layer is plural in quantity, and the plurality of electrode layers correspond to each of the reflective parts in position; wherein a length of each of the plurality of electrode layers in a first direction is less than or equal to a length of each of the plurality of first transparent conductive layers in the first direction.

14. The vertical-cavity surface-emitting laser device according to claim 8, wherein the first transparent conductive layer is a metal film or an indium tin oxide layer.
